(19) United States
(12) Patent Application Publication
(10) Pub. No.: US 2026/0254196 A1
(43) Pub. Date: Aug. 27, 2026

(54) SELF-STARTING FIGURE-9 CAVITY LASERS BASED ON EXTERNAL SIGNAL INJECTION

(71) Applicant: ANHUI HUACHUANG HONGDU PHOTOELECTRIC TECHNOLOGY CO., LTD., Hefei, Anhui (CN)

(72) Inventors: Hanxiao WANG, Hefei (CN); Qingbang SHU, Hefei (CN); Gensheng ZHA, Hefei (CN); Jian SHU, Hefei (CN); Shiqiang YANG, Hefei (CN); Chengbao FENG, Hefei (CN); Weiqing GAO, Hefei (CN)

(73) Assignee: ANHUI HUACHUANG HONGDU PHOTOELECTRIC TECHNOLOGY CO., LTD., Hefei, Anhui (CN)

(21) Appl. No.: 19/301,907

(22) Filed: Aug. 15, 2025

(30) Foreign Application Priority Data
Feb. 24, 2025 (CN) 202510200186.3

(51) Int. Cl. H01S 5/065; H01S 5/04; H01S 5/06; H01S 5/10; H01S 5/50

(52) U.S. Cl. CPC H01S 5/0657; H01S 5/041; H01S 5/0604; H01S 5/1028; H01S 5/50

(57) ABSTRACT

The present disclosure relates to a self-starting figure-9 cavity laser based on external signal injection. The laser includes a nonlinear amplifying loop mirror, a linear arm, and a 2×2 polarization-maintaining fiber coupler. The laser further includes an external optical signal source, a 3-port polarization-maintaining fiber circulator, a photodetector, and a control module. A first port and a second port of the 2×2 polarization-maintaining fiber coupler are connected to the linear arm and a second port of the 3-port polarization-maintaining fiber circulator, respectively. A third port and a fourth port of the 2×2 polarization-maintaining fiber coupler are connected to the nonlinear amplifying loop mirror. A first port and a third port of the 3-port polarization-maintaining fiber circulator are connected to the external optical signal source and the photodetector, respectively. The control module is connected to the nonlinear amplifying loop mirror, the external optical signal source, and the photodetector.

### CROSS-REFERENCE TO RELATED APPLICATIONS

This application claims priority to Chinese Application No. 202510200186.3, filed Feb. 24, 2025, the entire contents of which are incorporated herein by reference.

### TECHNICAL FIELD

The present disclosure relates to the technical field of fiber lasers, and in particular, relates to a self-starting figure-9 cavity laser based on external signal injection.

### BACKGROUND

In ultrafast lasers, mode-locking technology is a key method for achieving ultrashort pulse laser output. By adjusting the state of the laser cavity, a fixed and stable phase difference can be established between the numerous longitudinal modes within the laser cavity, thus transforming the laser output from continuous-wave operation to periodic light pulses. Fast self-starting mode-locking in a figure-9 cavity (a phase-biased nonlinear amplifying loop mirror) typically requires high pump current initially, resulting in multipulse operation, and subsequent reduction of pump current progressively eliminates excess pulses to achieve a fundamental frequency single-pulse state. The traditional 9-cavity mode-locked fiber laser can achieve mode-locking with high stability and high repetition rate, but the mode-locking start-up time exhibits a long-tail distribution (where a part of the mode-locking process may be extremely prolonged). Currently, the system still requires a high-power pump source for start-up, resulting in power inefficiency and elevated costs.

Therefore, it is desired to develop a self-starting figure-9 cavity laser based on external signal injection, which can help to reduce power waste and input costs associated with mode-locking.

### SUMMARY

One or more embodiments of the present disclosure provide a self-starting figure-9 cavity laser based on external signal injection. The self-starting figure-9 cavity laser comprises a nonlinear amplifying loop mirror, a linear arm, and a 2×2 polarization-maintaining fiber coupler. The self-starting figure-9 cavity laser further comprises an external optical signal source, a 3-port polarization-maintaining fiber circulator, a photodetector, and a control module. A first port and a second port of the 2×2 polarization-maintaining fiber coupler are connected to the linear arm and a second port of the 3-port polarization-maintaining fiber circulator, respectively. A third port and a fourth port of the 2×2 polarization-maintaining fiber coupler are connected to the nonlinear amplifying loop mirror. A first port and a third port of the 3-port polarization-maintaining fiber circulator are connected to the external optical signal source and the photodetector, respectively. The control module is connected to the nonlinear amplifying loop mirror, the external optical signal source, and the photodetector.

The present disclosure provides a self-starting figure-9 cavity laser based on external signal injection, which guides the nonlinear enhancement of the signal in the cavity by providing a high-intensity initial optical field, and the strong signal is more easily accessible to the positive feedback region of the cavity, so as to enable the cavity to enter the single-pulse mode-locked state. This eliminates the need for a high-power pump source, avoids power waste, and reduces costs.

### BRIEF DESCRIPTION OF THE DRAWINGS

The present disclosure will be further illustrated by way of exemplary embodiments, which will be described in detail by means of the accompanying drawings. These embodiments are not limiting, and in these embodiments, the same numbering denotes the same structure, wherein:

FIG. 1 is a schematic diagram illustrating a structure of a self-starting 9-cavity laser based on external signal injection according to some embodiments of the present disclosure;

FIG. 2 is a schematic diagram illustrating ports of a 2×2 polarization-maintaining fiber coupler and a 3-port polarization-maintaining fiber circulator according to some embodiments of the present disclosure;

FIG. 3 is a flowchart illustrating a mode-locking process according to some embodiments of the present disclosure;

FIG. 4 is a schematic diagram illustrating a mode-locking start effect according to some embodiments of the present disclosure.

Descriptions of the accompanying labels: 1, nonlinear amplifying loop mirror; 101, active polarization-maintaining fiber; 102, polarization-maintaining wavelength division multiplexer; 103, phase shifter; 104, passive polarization-maintaining fiber; 105, pump source; 2, linear arm; 201, output jumper connector; 202, polarization-maintaining fiber isolator; 203, polarization-maintaining fiber bragg grating; 3, 2×2 polarization-maintaining fiber coupler; 4, external optical signal source; 5, 3-port polarization-maintaining fiber circulator; 6, photodetector; 7, control module.

### DETAILED DESCRIPTION

In order to more clearly illustrate the technical solutions of the embodiments of the present disclosure, the accompanying drawings required to be used in the description of the embodiments will be briefly described below. Obviously, the accompanying drawings in the following description are only some examples or embodiments of the present disclosure, and it is possible for a person of ordinary skill in the art to apply the present disclosure to other similar scenarios according to these drawings without creative labor. Unless obviously obtained from the context or the context illustrates otherwise, the same numeral in the drawings refers to the same structure or operation.

It should be understood that, as used herein, the terms “system”, “device”, “unit”, and/or “module” as used herein is a way to distinguish between different components, elements, parts, sections, or assemblies at different levels. However, said words may be replaced by other expressions if other words accomplish the same purpose.

As shown in the specification and the claims, unless the context clearly suggests an exception, the words “a”, “an”, and/or “the” do not refer specifically to the singular, but may also include the plural. In general, the terms “including” and “comprising” only suggest the inclusion of explicitly identified steps and elements that do not constitute an exclusive list, and the method or apparatus may also include other steps or elements.

Flowcharts are used in the present disclosure to illustrate operations performed by a system according to embodiments of the present disclosure. It should be appreciated that the preceding or following operations are not necessarily performed in an exact sequence. Instead, steps can be processed in reverse order or simultaneously. Also, it is possible to add other operations to these processes or remove a step or steps from them.

A mode-locked laser typically relies on spontaneous radiated noise within a cavity to trigger the formation of short pulses. As a noise signal propagates within the cavity, the noise signal begins to match the mode spectrum within the cavity. Due to saturation absorption mechanism artificially set in the cavity, the noise signal is screened and nonlinearly enhanced, so that the noise signal is prompted to focus on a specific frequency and phase. Ultimately, the optical signal within the cavity tends to stabilize and reach a mode-locked state. However, at a low pump power, the noise in the cavity is weak, making it difficult to initiate mode-locking. Therefore, the traditional 9-cavity laser requires a higher pump power to trigger mode-locking at startup and relies on random rise and fall, which is time-consuming.

Therefore, a self-starting figure-9 cavity laser (also referred to as the laser) based on external signal injection is provided to reduce power waste, improve efficiency, and reduce cost.

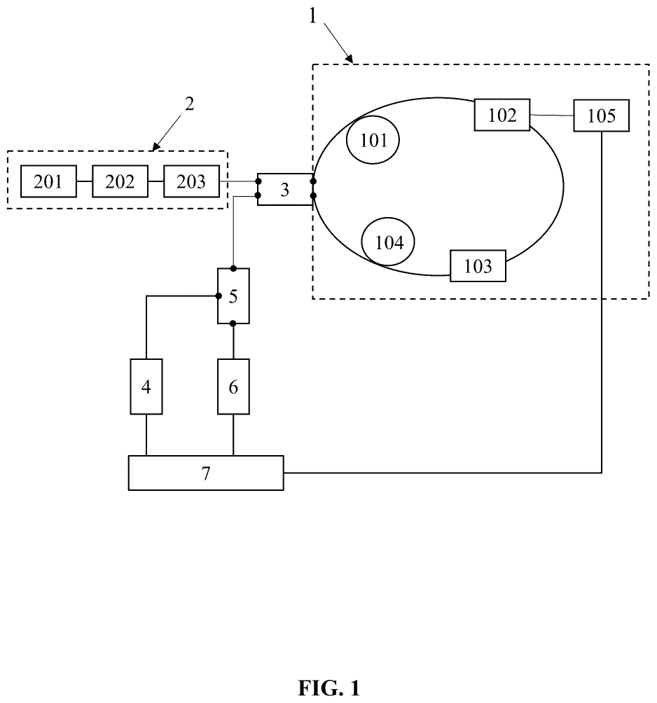

FIG. 1 is a schematic diagram illustrating a structure of a self-starting 9-cavity laser based on external signal injection according to some embodiments of the present disclosure.

In some embodiments, as shown in FIG. 1, a self-starting 9-cavity laser (also referred to as a self-starting figure-9 cavity laser) based on external signal injection may include a nonlinear amplifying loop mirror 1, a linear arm 2, a 2×2 polarization-maintaining fiber coupler 3, an external optical signal source 4, a 3-port polarization-maintaining fiber circulator 5, a photodetector 6, and a control module 7.

In some embodiments, the 2×2 polarization-maintaining fiber coupler 3 includes a plurality of ports. For example, the 2×2 polarization-maintaining fiber coupler may include 4 ports. The 3-port polarization-maintaining fiber circulator 5 includes 3 ports.

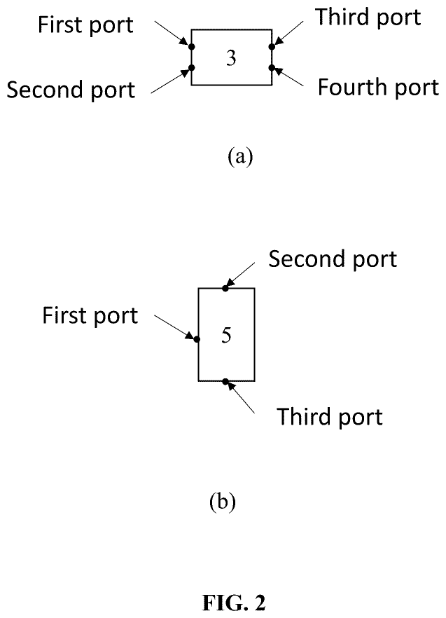

FIG. 2 is a schematic diagram illustrating ports of a 2×2 polarization-maintaining fiber coupler and a 3-port polarization-maintaining fiber circulator according to some embodiments of the present disclosure. Merely by way of example, as shown in (a) of FIG. 2, the 2×2 polarization-maintaining fiber coupler 3 includes a first port, a second port, a third port, and a fourth port. The first port and the second port are input ports, and the third port and the fourth port are output ports. As shown in (b) of FIG. 2, the 3-port polarization-maintaining fiber circulator 5 includes a first port, a second port, and a third port. The first port and the third port are input ports, and the second port is an output port.

In some embodiments, the first port and the second port of the 2×2 polarization-maintaining fiber coupler 3 are connected to the linear arm 2 and the second port of the 3-port polarization-maintaining fiber circulator 5, respectively. The third port and the fourth port of the 2×2 polarization-maintaining fiber coupler 3 are connected to the nonlinear amplifying loop mirror 1. The first port and the third port of the 3-port polarization-maintaining fiber circulator 5 are connected to the external optical signal source 4 and the photodetector 6, respectively. The control module 7 is connected to the nonlinear amplifying loop mirror 1, the external optical signal source 4, and the photodetector 6, respectively.

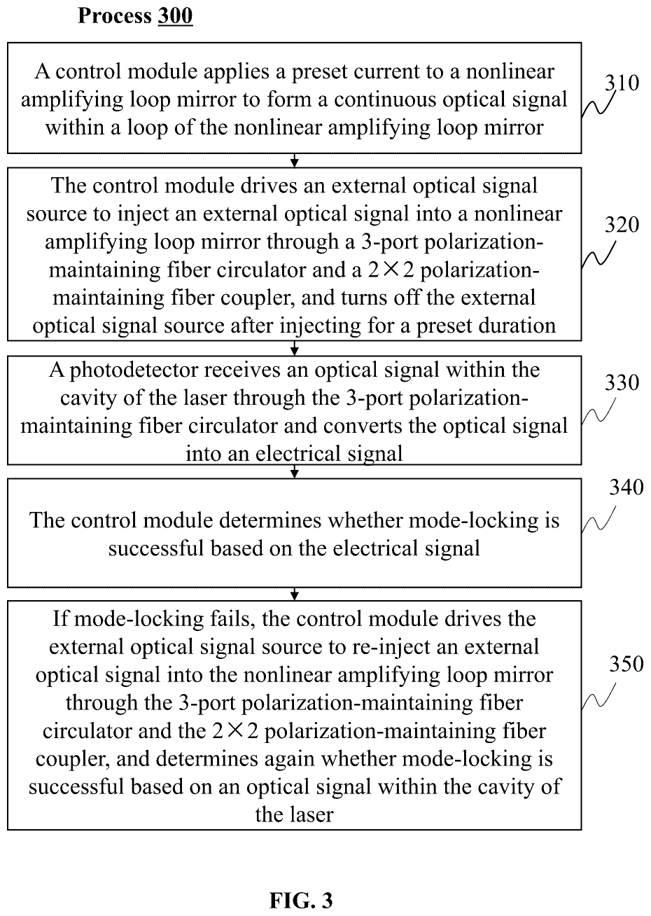

The nonlinear amplifying loop mirror 1 refers to a common artificial saturable absorber, which is configured to realize the amplification and reflection of an optical signal through a nonlinear effect. In some embodiments, the nonlinear amplifying loop mirror 1 may be a nonlinear optical structure based on a fiber. More descriptions regarding the nonlinear amplifying loop mirror may be found in FIG. 3 and the related descriptions.

The linear arm 2 refers to a linear part of the cavity of the laser, which is configured to provide a transmission path for an optical signal. In some embodiments, the linear arm 2 may be a polarization-maintaining fiber or a common single-mode fiber. More descriptions regarding the linear arm may be found in the related descriptions below.

The 2×2 polarization-maintaining fiber coupler 3 is configured to distribute the optical signal to different paths to achieve cavity closure and optical signal coupling in the laser system.

In some embodiments, the 2×2 polarization-maintaining fiber coupler has a splitting ratio of 60:40. 60% of an input optical power of the 2×2 polarization-maintaining fiber coupler 3 is output from the third port, and 40% of the input optical power is output from the fourth port.

The splitting ratio refers to a power distribution ratio of the third port to the fourth port of the 2×2 polarization-maintaining fiber coupler 3. The input optical power refers to a total power of the optical signal input to the 2×2 polarization-maintaining fiber coupler 3.

In some embodiments, the splitting ratio may also be set to 50:50, 70:30, 80:20, etc.

In some embodiments of the present disclosure, the distribution of the input optical power can be precisely controlled to satisfy the requirements of a particular application scenario by setting the splitting ratio.

The external optical signal source 4 may provide an initial optical signal to start the laser. The optical signal may be an optical pulse signal.

In some embodiments, the external optical signal source 4 may be any one of a pulse semiconductor laser, a Q-switched fiber laser, a modulated continuous-wave (CW) laser, and a mode-locked laser.

The 3-port polarization-maintaining fiber circulator 5 is configured to achieve directional transmission of the optical signal, which ensures that the optical signal, from the external optical signal source 4, is injected into the nonlinear amplifying loop mirror 1 and output to the photodetector 6.

The photodetector 6 is configured to detect and process the optical signal. For example, the photodetector 6 may be a PIN photodiode, an avalanche photodiode (APD), or other detectors.

The control module 7 is configured to control an operation of the laser. In some embodiments, the control module 7 may include a processor. For example, the control module 7 may include a microprocessor, a control circuitry for a Field-Programmable Gate Array (FPGA), a Microcontroller (MCU), an Embedded Processor, a Digital Signal Processor (DSP), or the like, or any combination thereof.

In some embodiments, the mode-locking process of the laser may be achieved by the nonlinear amplifying loop mirror, the 3-port polarization-maintaining fiber circulator, the 2×2 polarization-maintaining fiber coupler, the external optical signal source, a photodetector, and the control module, and more descriptions may be found in FIG. 3 and the related descriptions.

Some embodiments of the present disclosure include, but are not limited to, the following beneficial effects. (1) The laser achieves efficient, stable and controllable laser output through the synergy of external signal injection and the control module; (2) The laser can achieve self-startup through the injection of an external optical signal source, thereby avoiding a threshold problem or a startup difficulty that the traditional laser may encounter during startup, and improving the reliability and stability of the laser. (3) The introduction of the photodetector enables an output state of the laser to be monitored in real time, thereby facilitating the control module to adjust based on feedback from the photodetector and further enhancing the stability and performance of the laser.

In some embodiments, the nonlinear amplifying loop mirror 1 includes an active polarization-maintaining fiber 101, a polarization-maintaining wavelength division multiplexer 102, a phase shifter 103, a passive polarization-maintaining fiber 104, and a pump source 105. Under excitation of a preset current, the pump source 105 emits a pump light, the pump light being incident on the active polarization-maintaining fiber 101 via the polarization-maintaining wavelength division multiplexer 102 to generate a continuous optical signal within a loop of the nonlinear amplifying loop mirror 1, the continuous optical signal propagating bidirectionally in clockwise and counterclockwise directions within the loop. More descriptions regarding the continuous optical signal may be found in FIG. 3 and the related descriptions.

In some embodiments, the active polarization-maintaining fiber 101, the polarization-maintaining wavelength division multiplexer 102, the phase shifter 103, and the passive polarization-maintaining fiber 104 are connected sequentially, and the pump source 105 is connected to the polarization-maintaining wavelength division multiplexer 102.

The active polarization-maintaining fiber 101 is used for transmitting and amplifying the optical signal while maintaining a polarization state of light. In some embodiments, the active polarization-maintaining fiber 101 includes a gain medium, such as a rare earth element. For example, the active polarization-maintaining fiber 101 may be a Polarization-Maintaining Erbium-Doped Fiber (PM-EDF), a Polarization-Maintaining Ytterbium-Doped Fiber (PM-YDF), etc.

In some embodiments, the active polarization-maintaining fiber may be a polarization-maintaining ytterbium-doped silica fiber-high intensity-high power (PM-YSF-HI-HP), which can effectively maintain the polarization state of the laser and reduce the crosstalk of the polarization mode, thereby improving output stability and beam quality of the laser, and exhibiting high-gain characteristics, enabling efficient optical amplification and making it suitable for high-power laser systems.

The polarization-maintaining wavelength division multiplexer 102 is configured to couple pump light into an optical fiber while maintaining the polarization state of the light. The pump light refers to light generated by the pump source 105 for excitation of the gain medium in the active polarization-maintaining fiber 101, thereby amplifying the optical signal.

The phase shifter 103 is configured to introduce a phase difference.

In some embodiments, the phase shifter has a phase delay of −π/2. For example, the phase shifter may utilize a non-reciprocal phase shifter having a phase delay of −π/2.

The phase of the optical signal can be precisely adjusted through the phase delay of −π/2, thereby optimizing the startup performance of the laser.

The passive polarization-maintaining fiber 104 is configured to transmit the optical signal and maintain the polarization state of the light. There is no gain medium in the passive polarization-maintaining fiber 104.

The pump source 105 is configured to generate the pump light. For example, the pump source 105 may be a semiconductor diode.

In some embodiments, the pump source may be a semiconductor diode with a wavelength of 980 nm. The semiconductor diode pump source with the wavelength of 980 nm is well-matched to the absorption spectrum of the PM-YSF-HI-HP, thereby improving the pumping efficiency and reducing the energy loss.

In some embodiments, the pump source may also be a semiconductor diode with other wavelengths.

In some embodiments, the control module 7 may control the nonlinear amplifying loop mirror 1 to apply the preset current, and under the excitation of the preset current, the pump source 105 emits the pump light. The pump light may be incident on the active polarization-maintaining fiber 101 via the polarization-maintaining wavelength division multiplexer 102, and the active polarization-maintaining fiber 101 generates stimulated radiation to generate the continuous optical signal within the loop of the nonlinear amplifying loop mirror 1 by a gain effect of the gain medium. The continuous optical signal is propagated bidirectionally in clockwise and counterclockwise directions within the loop of the nonlinear amplifying loop mirror 1.

In some embodiments of the present disclosure, a change of the polarization state is effectively suppressed by using polarization-maintaining components such as the active polarization-maintaining fiber 101, the polarization-maintaining wavelength division multiplexer 102, and the phase shifter 103, thereby improving the stability of the laser output. The nonlinear phase shift is achieved under the phase shifter 103 and an asymmetry effect of positions in the active polarization-maintaining fiber 101, thereby enhancing the modulation depth of the laser to improve the self-starting performance of the laser.

In some embodiments, as shown in FIG. 1, the linear arm 2 includes an output jumper connector 201, a polarization-maintaining fiber isolator 202, and a polarization-maintaining fiber bragg grating 203. The output jumper connector 201, the polarization-maintaining fiber isolator 202, and the polarization-maintaining fiber bragg grating 203 are connected in sequence.

The output jumper connector 201 refers to an outlet for outputting the optical signal. In some embodiments, the output jumper connector 201 is configured to extract a stably mode-locked optical signal within the cavity of the laser from the laser to enable external applications.

Stably mode-locking within the cavity of the laser refers to the output stability of the optical signal output by the cavity of the laser. In some embodiments, the control module 7 may determine the stably mode-locking within the cavity of the laser in various ways. For example, the control module 7 may determine a mode-locking within the cavity by comparing an output signal frequency of the laser obtained via measurement to a preset threshold. The preset threshold may be set empirically.

The cavity of the laser refers to a structure of the laser that generates a laser resonance cavity or an optical resonance cavity. For example, the cavity of the laser may be a cavity formed by an annular structure of the nonlinear amplifying loop mirror 1.

The external applications refer to actual scenarios or functional modules in which the output optical signal is used outside the laser. For example, the external applications may be a fiber optic communication system, a laser processing device, etc.

In some embodiments, the output jumper connector 201 may transmit a laser signal to the fiber optic communication system or the laser processing device.

The polarization-maintaining fiber isolator 202 is configured to unidirectionally transmit the optical signal to the output jumper connector 201.

In some embodiments, the polarization-maintaining fiber isolator 202 may utilize the Faraday effect to allow the optical signal to pass through in a forward direction of transmission and be blocked in a reverse direction of transmission. The forward direction refers to a direction in which the optical signal is transmitted from the polarization-maintaining fiber bragg grating 203 to the output jumper connector 201. The reverse direction refers to a direction in which the optical signal is transmitted from the output jumper connector 201 to the polarization-maintaining fiber bragg grating 203.

The polarization-maintaining fiber bragg grating 203 is configured to split light transmitted from the 2×2 polarization-maintaining fiber coupler 3 into two paths, one path is reflected to the 2×2 polarization-maintaining fiber coupler 3, and another path is transmitted to the polarization-maintaining fiber isolator 202.

In some embodiments, the polarization-maintaining fiber bragg grating 203 may selectively reflect light of a particular wavelength to the 2×2 polarization-maintaining fiber coupler 3 through a periodic change of a refractive index, so that the reflected light is allowed to enter into the nonlinear amplifying loop mirror 1 (i.e., the cavity of the laser) through the 2×2 polarization-maintaining fiber coupler 3, thereby enhancing the mode-locking effect.

In some embodiments, the polarization-maintaining fiber bragg grating 203 is a large-dispersion narrowband chirped fiber grating or a small-dispersion wideband chirped fiber grating. In some embodiments, the polarization-maintaining fiber bragg grating 203 has a reflectivity of 20%, a center wavelength of 1030 nm, and a bandwidth of 17 nm.

In some embodiments, the polarization-maintaining fiber bragg grating 203 has a reflectivity of 20%, a center wavelength of 1064 nm, and a bandwidth of 2 nm.

In some embodiments, the polarization-maintaining fiber bragg grating 203 may reflect 20% of the optical power transmitted by the 2×2 polarization-maintaining fiber coupler 3 back to the 2×2 polarization-maintaining fiber coupler 3, and transmit the remaining 80% of the optical power to the polarization-maintaining fiber isolator 202.

In some embodiments of the present disclosure, the energy is effectively utilized by setting the reflectivity of the polarization-maintaining fiber bragg grating 203 to 20%, while configuring different center wavelengths of the polarization-maintaining fiber bragg grating 203 to accommodate common laser wavelengths, and wavelength selectivity and a signal-noise ratio of the laser are improved by setting different bandwidths of the polarization-maintaining fiber bragg grating 203.

In some embodiments, after the mode-locking is stabilized, the optical signal amplified by the nonlinear amplifying loop mirror 1 is output to the polarization-maintaining fiber bragg grating 203 through the first port of the 2×2 polarization-maintaining fiber coupler 3, and the output jumper connector 201 may extract the optical signal out of the laser for the external applications.

In some embodiments of the present disclosure, the optical signal can only be unidirectionally transmitted to the output jumper connector 201 by setting the polarization-maintaining fiber isolator 202, thereby preventing the reflected light from returning to the laser cavity. The polarization-maintaining fiber bragg grating 203 and the polarization-maintaining fiber isolator 202 can ensure the polarization stability of the optical signal during transmission. The output jumper connector can extract the optical signal from the laser for the external applications, thereby improving the practicality and application range of the laser. An internal structure of the laser is simplified by integrating the output jumper connector 201, the polarization-maintaining fiber bragg grating 203, and the polarization-maintaining fiber isolator 202 onto the linear arm 2, thereby reducing the complexity of manufacturing and maintenance.

FIG. 3 is a flowchart illustrating a mode-locking process according to some embodiments of the present disclosure. In some embodiments, as shown in FIG. 3, a mode-locking process 300 of a laser includes operation 310-operation 350.

In 310, a control module applies a preset current to a nonlinear amplifying loop mirror to form a continuous optical signal within a loop of the nonlinear amplifying loop mirror.

The preset current refers to a current required to complete the mode-locking process. In some embodiments, a value of the preset current may be preset based on a priori experience.

The continuous optical signal refers to an optical signal that propagates in an uninterrupted loop. In some embodiments, the continuous optical signal is in a form of consecutive monopulse and/or a multipulse.

In some embodiments of the present disclosure, the continuous optical signal is generated by driving the nonlinear amplifying loop mirror by the preset current, thereby providing a basis for subsequent mode-locking operation.

In 320, the control module drives an external optical signal source to inject an external optical signal into a nonlinear amplifying loop mirror through a 3-port polarization-maintaining fiber circulator and a 2×2 polarization-maintaining fiber coupler, and turns off the external optical signal source after injecting for a preset duration. More descriptions regarding the external optical signal source may be found in FIG. 1 and the related descriptions.

The external optical signal refers to an optical signal generated by the external optical signal source. In some embodiments, an injection parameter of the external optical signal may be set based on requirements or experience.

The injection parameter refers to a key control parameter that drives the external optical signal source to output the external optical signal. For example, the injection parameter includes a repetition frequency, an injection power, an injection pulse width, etc., for continuously injecting the external optical signal.

The repetition frequency refers to a count of pulses emitted per unit of time (e.g., per second) when the external optical signal source periodically outputs an optical pulse. The injection power refers to an optical power when the external optical signal source outputs the optical signal. The injection pulse width refers to a duration of a pulse of a single injected external optical signal.

In some embodiments, the external optical signal has the center wavelength of 1030 nm, the injection power of 1 mW, the injection pulse width of 1 ns, and the repetition frequency of 2000 kHz. The center wavelength of the external optical signal is the same as the operating wavelength of the laser.

The preset duration may be set according to requirements or experience.

In some embodiments, two noise signals propagating bidirectionally in clockwise and counterclockwise directions within the loop generate a nonlinear phase shift under a phase shifter 103 and an asymmetry effect of positions in an active polarization-maintaining fiber 101.

In some embodiments, the two noise signals include the continuous optical signal and the external optical signal. More descriptions regarding the continuous optical signal and the external optical signal may be found in related descriptions.

The nonlinear phase shift refers to a nonlinear phase change of the noise signals. The asymmetry effect of the position in the active polarization-maintaining fiber 101 refers to a phenomenon where asymmetries at different positions within the active polarization-maintaining fiber 101 cause a difference between a nonlinear phase shift of the optical signal in the clockwise direction and a nonlinear phase shift of the optical signal in the counterclockwise direction.

In some embodiments, the optical signals in the two directions within the loop interfere at the 2×2 polarization-maintaining fiber coupler 3, and are incident on the polarization-maintaining fiber bragg grating 203 and the 3-port polarization-maintaining fiber circulator 5 via the first port and the second port of the 2×2 polarization-maintaining fiber coupler 3, respectively.

The formation of the mode-locking can be facilitated by adjusting an operating state of the nonlinear amplifying loop mirror through the injection of the external optical signal.

In 330, a photodetector receives an optical signal within the cavity of the laser through the 3-port polarization-maintaining fiber circulator and converts the optical signal into an electrical signal.

The optical signal within the cavity of the laser refers to an optical signal amplified by the nonlinear amplifying loop mirror 1 within the cavity of the laser. More descriptions regarding the cavity of the laser may be found in FIG. 1 and the related descriptions.

In some embodiments, the 3-port polarization-maintaining fiber circulator 5 has high isolation. For example, the optical signal incident via the first port is emitted via the second port; the optical signal incident via the second port is emitted via the third port without disrupting optical signal intensity.

In 340, the control module determines whether mode-locking is successful based on the electrical signal. More descriptions may be found in the operation 350 and the related descriptions.

The electrical signal refers to a voltage signal obtained by converting the optical signal in the cavity received by the photodetector. The electrical signal may reflect feature parameters of the optical signal output by the laser. The feature parameters may reflect a time-domain feature and a frequency-domain feature of the optical signal, such as a fundamental frequency.

In 350, if mode-locking fails, the control module drives the external optical signal source to re-inject an external optical signal into the nonlinear amplifying loop mirror through the 3-port polarization-maintaining fiber circulator and the 2×2 polarization-maintaining fiber coupler, and determines again whether mode-locking is successful based on an optical signal within the cavity of the laser.

In some embodiments, the control module 7 may extract the feature parameters in the electrical signal, and in response to determining that the feature parameters in the electrical signal satisfies a preset mode-locking condition, determine that the mode-locking is successful; otherwise, determine that the mode-locking fails, and adjust the injection parameter of the external optical signal source to obtain an adjusted injection parameter; and return to the operation 320 to control the external optical signal source to re-inject the external optical signal based on the adjusted injection parameter.

The preset mode-locking condition may be set according to requirements or experience. For example, the preset mode-locking condition may be that the feature parameters of the electrical signal are in a preset electrical signal range. The preset electrical signal range may be set based on requirements or experience. The preset electrical signal range includes a standard fundamental frequency range. The standard fundamental frequency range refers to a range of standard frequencies determined by a length of the cavity of the laser.

In some embodiments, the preset mode-locking condition is satisfied when a pulse frequency of the electrical signal is in the standard fundamental frequency range.

In some embodiments, the control module 7 is further configured to: determine a matching value for mode-locking based on an amplitude deviation between the electrical signal and a preset electrical signal; adjust the injection parameter of the external optical signal source 4 of the laser based on changes in matching values of a plurality of historical electrical signals during the mode-locking process.

The preset electrical signal refers to an electrical signal when the laser is in a stable mode-locking state. In some embodiments, the preset electrical signal may be obtained experimentally. The preset electrical signal may also be determined in other feasible ways, such as manually preset empirically.

The amplitude deviation refers to a deviation value (taking an absolute value) between the electrical signal measured currently and the preset electrical signal. The smaller the amplitude deviation is, the closer the current mode-locking state is to an ideal state.

In some embodiments, the control module 7 determines the amplitude deviation by summing up a plurality of deviation values between continuous electrical signals at a plurality of time points and the preset electrical signal.

In some embodiments, the control module 7 may calculate the fundamental frequency based on the electrical signal measured currently, and take the minimum deviation value between the fundamental frequency and the standard fundamental frequency range as the amplitude deviation.

The matching value for mode-locking is used to characterize a success degree of the mode-locking under the current electrical signal, and the higher the matching value for mode-locking, the greater the success degree of the mode-locking. For example, the matching value is in a range of [0, 1]. A matching value of 1 indicates that the current electrical signal fully meets a mode-locking state, a matching value close to 1 indicates that the current electrical signal is close to a mode-locking success condition, and a matching value much less than 1 indicates that an output feature deviates from the mode-locking state by a large amount.

In some embodiments, the control module 7 may normalize the amplitude deviation between the electrical signal and the preset electrical signal to obtain a normalized amplitude deviation; determine the matching value based on the normalized amplitude deviation. The normalization manner may be Min-Max normalization, Z-score normalization, etc. The matching value of the mode-locking is negatively correlated with the normalized amplitude deviation. In some embodiments, the matching value of the mode-locking may be calculated by equation (1) as follows:

$$M = 1 - D$$

where M denotes the matching value of the mode-locking; D denotes the normalized amplitude deviation.

More descriptions regarding the injection parameter may be found in operation 320 in FIG. 3 and the related descriptions.

In some embodiments of the present disclosure, a more efficient mode-locking control can be realized by determining the matching value of the mode-locking corresponding to the electrical signal and dynamically adjusting the injection parameter of the external optical signal according to the change of the matching value, thereby enhancing the stability of the laser and the response speed.

In some embodiments, the control module 7 is further configured to: adjust the injection parameter of the external optical signal source of the laser according to the plurality of historical electrical signals during the mode-locking process.

In some embodiments, each mode-locking process may include a plurality of mode-locking attempts, and each mode-locking attempt includes an electrical signal sample. Therefore, each mode-locking process includes a plurality of historical electrical signals.

In some embodiments, the control module 7 may adjust the injection parameter of the external optical signal source 4 based on the plurality of historical electrical signals in various ways. For example, the control module 7 may set an initial injection parameter and control the external optical signal source 4 to start injecting the optical signal based on the initial injection parameter for a first mode-locking attempt; in subsequent rounds of mode-locking attempts, each round of mode-locking attempt adjusts the injection parameter based on the injection parameter of the previous round according to a preset rule.

The initial injection parameter refers to an injection parameter of the external optical signal source 4 injecting the optical signal for the first time. The initial injection parameter includes an initial repetition frequency, an initial injection power, and an initial injection pulse width.

The preset rule may be set empirically. For example, the preset rule may be that a value of the injection parameter increases linearly with time, or the value of the injection parameter increases or decreases periodically (e.g., increases or decreases in a sawtooth form or a sinusoidal form).

In some embodiments, for each mode-locking attempt among the plurality of mode-locking attempts, the control module 7 may control the photodetector 6 to continuously collect the electrical signal, extract a fundamental frequency corresponding to the electrical signal, and determine the adjusted injection parameter based on the fundamental frequency. In some embodiments, the control module 7 may select an injection parameter corresponding to a time when the fundamental frequency is closest to the standard fundamental frequency range, as the adjusted injection parameter.

In some embodiments of the present disclosure, the injection parameter of the external optical signal source is adjusted based on the plurality of historical electrical signals during the mode-locking process, and feedback regulation is carried out based on the plurality of historical electrical signals, so that the laser can adaptively adjust the injection parameter of the external optical signal according to an actual operating condition, thereby reducing human intervention, and improving the stability and the efficiency of mode-locking.

In some embodiments, the control module 7 is further configured to: determine the adjusted injection parameter by querying a vector database based on the plurality of historical electrical signals during the mode-locking process.

The vector database refers to a database for querying and storing the injection parameters. In some embodiments, the control module 7 may select historical mode-locking attempt records whose mode-locking effects meet a preset condition. For each of the historical mode-locking attempt records, the feature parameter (such as the fundamental frequency, etc.) of the electrical signal and an environmental parameter (such as a temperature, etc.) are converted into a feature vector. Each feature vector and corresponding injection parameters (including a repetition frequency, an injection power, and a fundamental frequency) of each feature vector are stored in the vector database. In some embodiments, the preset condition includes that the matching value for the mode-locking is greater than a preset threshold (e.g., 0.95).

In some embodiments, the control module 7 may construct a query vector based on a statistical value of the feature parameters (such as the fundamental frequency) of the plurality of historical electrical signals and a statistical value of the environmental parameters of the plurality of historical electrical signals during the mode-locking process. The query vector is input to the vector database to query a feature vector with the highest similarity; and an injection parameter corresponding to the feature vector is output and determined as the adjusted injection parameter. The statistical value may be an average or a variance, etc. The similarity is negatively correlated with a vector distance (such as a cosine distance, an Euclidean distance, etc.).

In some embodiments of the present disclosure, the control module 7 is able to rapidly and accurately adjust the injection parameter based on the plurality of historical electrical signals by using the vector database, thereby enhancing the performance and the automation level of the mode-locking process.

In some embodiments, the control module 7 is further configured to: determine an adjusted injection parameter through a signal parameter model based on the plurality of historical electrical signals during the mode-locking process.

The signal parameter model refers to a model for determining the adjusted injection parameter. In some embodiments, the signal parameter model is a machine learning model, e.g., a Neural Networks (NN) model, a Deep Neural Networks (DNN) model, etc.

In some embodiments, during each mode-locking process, an input to the signal parameter model includes a statistical value of the fundamental frequencies of the plurality of historical electrical signals and a statistical value of environmental parameters of the plurality of historical electrical signals, and an output of the signal parameter model includes the adjusted injection parameter (e.g., the repetition frequency, the injection power, the injection pulse width, etc.). The statistical value may be a mean or a median, etc.

The adjusted injection parameter is determined based on the plurality of historical electrical signals during the mode-locking process via the signal parameter model, which can deal with more complex electrical signals and improve the overall performance of the laser. The accuracy of parameter adjustment can be improved by outputting the adjusted injection parameters via the signal parameter model, thereby reducing human misjudgment.

In some embodiments, the control module 7 is further configured to: select either the vector database or the signal parameter model to determine the injection parameter based on distribution features of the plurality of historical electrical signals.

The distribution features refer to the statistical features of the plurality of historical electrical signals captured from the plurality of mode-locking attempts during the mode-locking process. The distribution features include a count of samples, a difference degree, etc., of all of the plurality of historical electrical signals captured by the plurality of mode-locking attempts during one mode-locking process.

The difference degree refers to a numerical fluctuation of the plurality of historical electrical signals in the feature parameters (e.g., the fundamental frequency). In some embodiments, the control module 7 may determine a statistical value of the fundamental frequencies corresponding to the plurality of historical electrical signals as the difference degree of the plurality of historical electrical signals. The statistical value may be a standard deviation, a variance, etc.

In some embodiments, in response to determining that the count of samples of the plurality of historical electrical signals is less than a preset count threshold or the difference degree is less than a preset difference threshold, the control module may select the vector database to determine the adjusted injection parameter. The preset count threshold and the preset difference threshold may be set empirically.

In some embodiments, in response to determining that the count of samples of the plurality of historical electrical signals is greater than the preset count threshold and the difference degree is greater than the preset difference threshold, the control module may select the signal parameter model to determine the adjusted injection parameter.

In some embodiments of the present disclosure, a more flexible parameter adjustment manner is provided by selecting either a vector database or a signal parameter model to determine the injection parameter based on distribution features of the plurality of historical electrical signals. For example, for a scenario with a small amount of data, a stable state, and requirements for a fast response, the vector database is selected. For a scenario with a large amount of data, a complex state, and more environmental perturbations, the signal parameter model is selected.

It should be noted that when adjusting the injection parameters, the allowable adjustment range of the injection parameters is within a preset adjustment range. The preset adjustment range refers to an adjustment range of the injection parameter. The preset adjustment range may be set empirically.

In some embodiments, the control module 7 is further configured to: in response to determining that mode-locking is not successful after performing a preset count of adjustment operations on the injection parameter, control a pump source to increase an emission power to enhance an intensity of a pump light.

In some embodiments, in response to determining that the feature parameters in the electrical signal do not satisfy the preset mode-locking condition, the control module 7 may determine that the mode-locking is not successful. More descriptions regarding the preset mode-locking condition may be found in operation 350 in FIG. 3 and the related descriptions.

In some embodiments of the present disclosure, when the mode-locking is not successful after performing the preset count of adjustment operations, the emission power of the pump source is increased to increase the intensity of the pump light, thereby increasing the likelihood of the mode-locking being successful to avoid mode-locking failure over a long period of time.

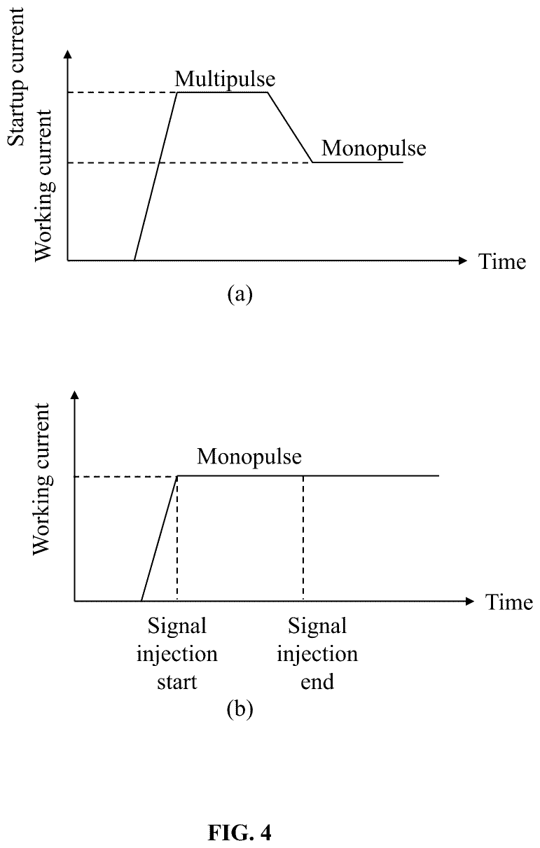

FIG. 4 is a schematic diagram illustrating a mode-locking start effect according to some embodiments of the present disclosure. As shown in FIG. 4, (a) in FIG. 4 illustrates a mode-locking process without injection of an external optical signal; and (b) in FIG. 4 illustrates a mode-locking process with injection of the external optical signal. Merely by way of example, as shown in FIG. 4, a preset current may be a startup current when there is no injection of the external optical signal. The startup current is greater than a working current.

The mode-locked laser usually relies on spontaneous emission noise within a cavity of the laser to trigger the formation of short pulses. As noise signals within the cavity propagate, the noise signals begin to match the mode spectrum within the cavity. Due to the saturation absorption mechanism set artificially in the cavity, the noise signal is screened and nonlinearly enhanced, thereby causing the noise signals to focus on specific frequencies and phases. Eventually, the optical signal within the cavity tends to stabilize and reach a mode-locking state. However, at low pump power, the noise within the cavity is relatively weak, making it difficult to start the mode-locking mode. Therefore, when starting up a traditional 9-cavity laser, it requires a relatively high pump power to trigger mode-locking and relies on random fluctuations, which takes a long time.

In some embodiments of the present disclosure, the energy of the noise signal within the laser cavity is enhanced by introducing an external optical signal to provide additional random rise and fall, making it easier for the noise signal within the cavity to reach the intensity required for triggering the mode-locking. This reduces pump power requirements and enables self-starting mode-locking at low pump current, reducing pump power waste. Furthermore, by providing a stronger initial signal, it eliminates the need for prolonged waiting as spontaneous radiation noise gradually accumulates, thus shortening the mode-locking time.

The basic concepts have been described above, and it will be apparent to those skilled in the art that the foregoing detailed disclosure serves only as an example and does not constitute a limitation of the present disclosure. While not expressly stated herein, various modifications, improvements, and amendments may be made to the present disclosure by those skilled in the art. Those types of modifications, improvements, and amendments are suggested in the present disclosure, so those types of modifications, improvements, and amendments remain within the spirit and scope of the exemplary embodiments of the present disclosure.

Also, the present disclosure uses specific words to describe the embodiments of the present disclosure. For example, “an embodiment” and/or “some embodiment” means a feature, structure, or characteristic associated with at least one embodiment of the present disclosure. Accordingly, it should be emphasized and noted that “one embodiment” or “an alternative embodiment” in different places in the present disclosure do not necessarily refer to the same embodiment. In addition, certain features, structures, or characteristics in one or more embodiments of the present disclosure may be suitably combined.

In addition, the order of processing elements and sequences, the use of numerical letters, or the use of other names described herein are not intended to qualify the order of the processes and methods of the present disclosure, unless expressly stated in the claims. While some embodiments of the present disclosure that are currently considered useful are discussed in the foregoing disclosure by way of various examples, it is to be understood that such details serve only illustrative purposes and that additional claims are not limited to the disclosed embodiments, rather, the claims are intended to cover all amendments and equivalent combinations that are consistent with the substance and scope of the embodiments of the present disclosure. For example, although the implementation of various components described above may be embodied in a hardware device, it may also be implemented as a software only solution, e.g., an installation on an existing server or mobile device.

Similarly, it should be noted that in order to simplify the presentation of the disclosure of the specification, and thereby aid in the understanding of one or more embodiments of the invention, the foregoing descriptions of the embodiments of the specification sometimes combine a variety of features into a single embodiment, accompanying drawings, or the description thereof. However, this method of disclosure does not imply that the objects of the present disclosure require more features than those mentioned in the claims. Rather, claimed subject matter may lie in less than all features of a single foregoing disclosed embodiment.

Numbers describing the number of compositions, attributes are used in some embodiments, and it should be understood that such numbers used in the description of embodiments, in some examples, use the modifiers “about”, “approximately”, or “generally”. Unless otherwise noted, the terms “about,” “approximate,” or “approximately” indicates that a ±20% variation in the stated number is allowed.

Correspondingly, in some embodiments, the numerical parameters used in the specification and claims are approximations, which can change depending on the desired characteristics of individual embodiments. In some embodiments, the numerical parameters should take into account the specified number of valid digits and employ general place-keeping. While the numerical domains and parameters used to confirm the breadth of their ranges in some embodiments of the present disclosure are approximations, in specific embodiments such values are set to be as precise as possible within a feasible range.

For each of the patents, patent applications, patent application disclosures, and other materials cited in the present disclosure, such as articles, books, specification sheets, publications, documents, etc, the entire contents thereof are hereby incorporated herein by reference. Application history documents that are inconsistent with or conflict with the contents of the present disclosure are excluded, as are documents (currently or hereafter appended to the present disclosure) that limit the broadest scope of the claims of the present disclosure. It should be noted that in the event of any inconsistency or conflict between the descriptions, definitions, and/or use of terms in the materials appended to the present disclosure and those set forth herein, the descriptions, definitions and/or use of terms in the present disclosure shall prevail.

Finally, it should be understood that the embodiments described in the present disclosure are used only to illustrate the principles of the embodiments of the present disclosure. Other deformations may also fall within the scope of the present disclosure. As such, as an example, not as a limitation, alternative configurations of embodiments of the present disclosure may be viewed as consistent with the teachings of the present disclosure. Correspondingly, the embodiments of the present disclosure are not limited to the embodiments expressly presented and described herein.

What is claimed is:

1. A self-starting figure-9 cavity laser based on external signal injection, wherein the self-starting figure-9 cavity laser comprises a nonlinear amplifying loop mirror, a linear arm, and a 2×2 polarization-maintaining fiber coupler; the self-starting figure-9 cavity laser further comprises an external optical signal source, a 3-port polarization-maintaining fiber circulator, a photodetector, and a control module; wherein:
a first port and a second port of the 2×2 polarization-maintaining fiber coupler are connected to the linear arm and a second port of the 3-port polarization-maintaining fiber circulator, respectively;
a third port and a fourth port of the 2×2 polarization-maintaining fiber coupler are connected to the nonlinear amplifying loop mirror;
a first port and a third port of the 3-port polarization-maintaining fiber circulator are connected to the external optical signal source and the photodetector, respectively; and
the control module is connected to the nonlinear amplifying loop mirror, the external optical signal source, and the photodetector.

2. The self-starting figure-9 cavity laser according to claim 1, wherein a mode-locking process of the self-starting figure-9 cavity laser includes:
applying, by the control module, a preset current to the nonlinear amplifying loop mirror to form a continuous optical signal within a loop of the nonlinear amplifying loop mirror;
driving, by the control module, the external optical signal source to inject an external optical signal into the nonlinear amplifying loop mirror through the 3-port polarization-maintaining fiber circulator and the 2×2 polarization-maintaining fiber coupler, and turning off the external optical signal source after injecting for a preset duration;
receiving, by the photodetector, an optical signal within a cavity of the self-starting figure-9 cavity laser through the 3-port polarization-maintaining fiber circulator and converting the optical signal into an electrical signal;
determining, by the control module, whether mode-locking is successful based on the electrical signal; and
if mode-locking fails, driving, by the control module, the external optical signal source to re-inject an external optical signal into the nonlinear amplifying loop mirror through the 3-port polarization-maintaining fiber circulator and the 2×2 polarization-maintaining fiber coupler, and determining again whether mode-locking is successful based on an optical signal within the cavity of the self-starting figure-9 cavity laser.

3. The self-starting figure-9 cavity laser according to claim 2, wherein the nonlinear amplifying loop mirror includes an active polarization-maintaining fiber, a polarization-maintaining wavelength division multiplexer, a phase shifter, a passive polarization-maintaining fiber, and a pump source, wherein:
under excitation of the preset current, the pump source emits pump light, the pump light being incident on the active polarization-maintaining fiber via the polarization-maintaining wavelength division multiplexer to generate the continuous optical signal within the loop of the nonlinear amplifying loop mirror, the continuous optical signal propagating bidirectionally in clockwise and counterclockwise directions within the loop; and
two noise signals propagating in the clockwise direction and the counterclockwise direction within the loop generate a nonlinear phase shift under the phase shifter and an asymmetry effect of positions in the active polarization-maintaining fiber, the two noise signals including the continuous optical signal and the external optical signal.

4. The self-starting figure-9 cavity laser according to claim 3, wherein the active polarization-maintaining fiber is a polarization-maintaining ytterbium-doped silica fiber-high intensity-high power (PM-YSF-HI-HP), and the pump source is a semiconductor diode with a wavelength of 980 nm.

5. The self-starting figure-9 cavity laser according to claim 3, wherein the phase shifter has a phase delay of −π/2.

6. The self-starting figure-9 cavity laser according to claim 2, wherein the linear arm includes an output jumper connector, a polarization-maintaining fiber isolator, and a polarization-maintaining fiber bragg grating, wherein:
the polarization-maintaining fiber bragg grating is configured to split light transmitted from the 2×2 polarization-maintaining fiber coupler into two paths, one path is reflected back to the 2×2 polarization-maintaining fiber coupler, and another path is transmitted to the polarization-maintaining fiber isolator;
the polarization-maintaining fiber isolator is configured to unidirectionally transmit the optical signal to the output jumper connector; and
the output jumper connector is configured to extract a stably mode-locked optical signal within the cavity of the self-starting figure-9 cavity laser from the self-starting figure-9 cavity laser to enable external applications.

7. The self-starting figure-9 cavity laser according to claim 6, wherein the polarization-maintaining fiber bragg grating has a reflectivity of 20%, a center wavelength of 1064 nm, and a bandwidth of 2 nm.

8. The self-starting figure-9 cavity laser according to claim 2, wherein the 2×2 polarization-maintaining fiber coupler has a splitting ratio of 60:40, 60% of an input optical power of the 2×2 polarization-maintaining fiber coupler is output from the third port, and 40% of the input optical power is output from the fourth port.

9. The self-starting figure-9 cavity laser according to claim 1, wherein the external optical signal source is any one of a pulse semiconductor laser, a Q-switched fiber laser, a modulated continuous-wave (CW) laser, and a mode-locked laser.
